(19) United States
(12) Patent Application Publication
(10) Pub. No.: US 2014/0130734 A1
(43) Pub. Date: May 15, 2014

(54) DEVICE FOR DEPOSITING ORGANIC MATERIAL

(71) Applicant: Samsung Display Co., Ltd., Yongin-City (KR)

(72) Inventors: Hyung-Tag LIM, Yongin-City (KR); Jin-Woo PARK, Yongin-City (KR)

(73) Assignee: Samsung Display Co., Ltd., Yongin-City (KR)

(21) Appl. No.: 14/064,432

(22) Filed: Oct. 28, 2013

(30) Foreign Application Priority Data
Nov. 14, 2012 (KR) 10-2012-0128887

(51) Int. Cl. H01L 51/00

(52) U.S. Cl. CPC H01L 51/0011
USPC 118/504

(57) ABSTRACT

A deposition device for depositing an organic material includes a supporting roll having a surface, the surface being configured to receive a flexible substrate thereon, the supporting roll being configured to rotate, a deposition source spaced apart from the supporting roll, the deposition source being configured to deposit the organic material on the flexible substrate on the supporting roll, and a mask positioned between the supporting roll and the deposition source, the mask including an opening configured to allow the organic material to pass from the deposition source to the supporting roll.

### CROSS-REFERENCE TO RELATED APPLICATION

This application claims priority to and the benefit of Korean Patent Application No. 10-2012-0128887 filed in the Korean Intellectual Property Office on Nov. 14, 2012, the entire content of which is incorporated herein by reference.

### BACKGROUND

1. Field

Embodiments relate to an organic material deposition device.

2. Description of the Related Art

Recently, an organic light emitting diode (OLED) display has received much attention as a display device for displaying images.

The OLED display includes an organic emission layer emitting light having its own color.

The above information disclosed in this Background section is only for enhancement of understanding of the background of the described technology and therefore it may contain information that does not form the prior art that is already known in this country to a person of ordinary skill in the art.

### SUMMARY

Embodiments are directed to a deposition device for depositing an organic material, the device including a supporting roll having a surface, the surface being configured to receive a flexible substrate thereon, the supporting roll being configured to rotate, a deposition source spaced apart from the supporting roll, the deposition source being configured to deposit the organic material on the flexible substrate on the supporting roll, and a mask positioned between the supporting roll and the deposition source, the mask including an opening configured to allow the organic material to pass from the deposition source to the supporting roll.

The organic material may form an organic emission layer of an organic light emitting diode display on the flexible substrate.

A plurality of deposition sources may be provided, the plurality of deposition sources including: a first deposition source, the first deposition source being positioned to face the surface of the supporting roll at a first side of the supporting roll, a second deposition source, the second deposition source being positioned to face the surface of the supporting roll at a second side of the supporting roll, and a third deposition source, the third deposition source being positioned to face the surface of the supporting roll at a third side of the supporting roll, and a plurality of masks may be provided, the plurality of masks including: a first mask positioned between the first deposition source and the surface of the supporting roll, a second mask positioned between the second deposition source and the surface of the supporting roll, and a third mask positioned between the third deposition source and the surface of the supporting roll.

The first deposition source, the second deposition source, and the third deposition source may be configured to deposit respective organic materials to form an organic emission layer of an organic light emitting diode display emitting light having different colors.

The deposition source and the mask may each be curved.

The surface of the supporting roll may have a predetermined curvature, and a surface of the deposition source and the mask may each have the predetermined curvature.

The deposition source and the mask may each be substantially planar.

The supporting roll may be configured to rotate about an axis and thereby translate the flexible substrate in front of the deposition source.

### BRIEF DESCRIPTION OF THE DRAWINGS

Features will become apparent to those of skill in the art by describing in detail example embodiments with reference to the attached drawings in which:

FIG. 1 is a view of an organic material deposition device according to the first example embodiment.

FIG. 2 is a view of an organic material deposition device according to the second example embodiment.

FIG. 3 is a view of an organic material deposition device according to the third example embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “on” another element, it can be directly on the other element, or one or more intervening elements may also be present. It will also be understood that when an element is referred to as being “under” another element, it can be directly under, or one or more intervening elements may also be present. It will also be understood that when an element is referred to as being “between” two elements, it can be the only element between the two elements, or one or more intervening elements may also be present. Like reference numerals refer to like elements throughout.

Furthermore, with example embodiments, detailed description is given for the constituent elements in the first example embodiment with reference to the relevant drawings by using the same reference numerals for the same constituent elements, while only different constituent elements from those related to the first example embodiment may be described in other example embodiments.

In addition, unless explicitly described to the contrary, the word “comprise” and variations such as “comprises” or “comprising” will be understood to imply the inclusion of stated elements but not the exclusion of any other elements.

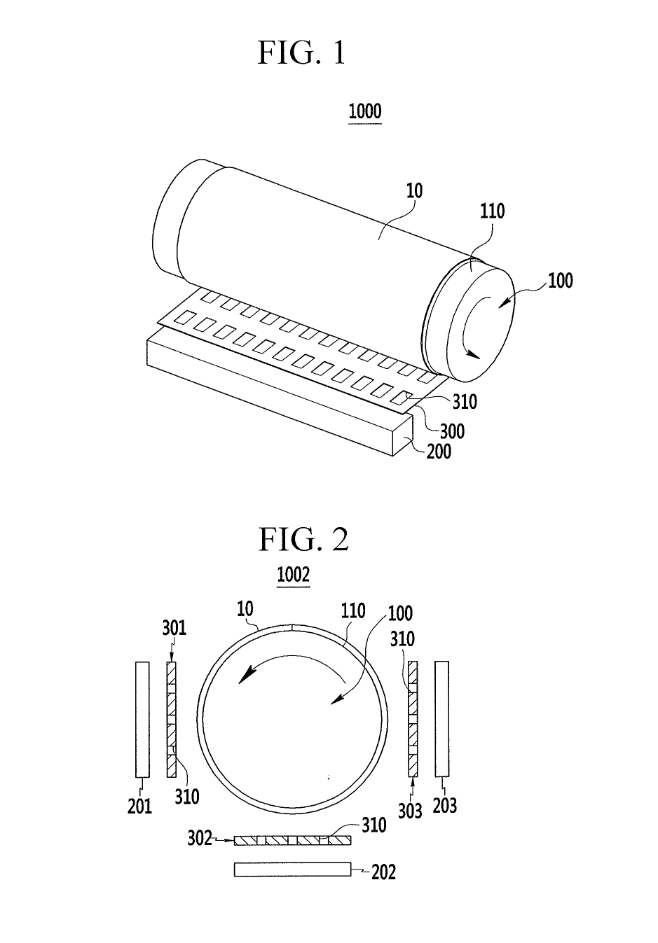

Next, referring to FIG. 1, an organic material deposition device according to a first example embodiment will be described.

FIG. 1 is a view of an organic material deposition device according to the first example embodiment.

In the example embodiment shown in FIG. 1, an organic material deposition device 1000 according to the first example embodiment deposits an organic material for an organic emission layer onto a flexible substrate 10, which is a deposition target, and includes a supporting roll 100, a deposition source 200, and a mask 300.

Here, the flexible substrate 10 may include a material such as a metal, a glass, and/or a polymer, and may include any suitable material that is flexible. Also, the flexible substrate 10 may include a pixel circuit including a plurality of thin film transistors, one or more capacitors, and a first electrode connected to the pixel circuit. The organic material may be deposited on the first electrode. After the organic material is deposited on the first electrode by the organic material deposition device 1000 to form the organic emission layer on the first electrode, a second electrode may be formed on the organic emission layer and an encapsulation part sealing the pixel circuit and the organic light emitting element (including the first electrode, the organic emission layer, and the second electrode) may be further formed on the second electrode to manufacture the organic light emitting diode (OLED) display.

In the present example embodiment, the supporting roll 100 is cylindrical, and the flexible substrate 10 is rolled at a surface 110 of the supporting roll 100. The flexible substrate 10 may be wrapped entirely around or part way around the supporting roll 100. The supporting roll 100 is itself rotated, and the organic material that is evaporated from the deposition source 200 is deposited on the entire surface of the flexible substrate 10 through the mask 300 by the rotation of the supporting roll 100. A constitution supporting the supporting roll 100 and simultaneously rotating the supporting roll 100 such as a bearing may be positioned at both ends of the supporting roll 100.

The deposition source 200 is positioned to be spaced apart from the supporting roll 100 by a predetermined interval. The deposition source 200 may evaporate the organic material in the direction of the supporting roll 100 to deposit the organic material on the flexible substrate 10 that is on the surface of the supporting roll 100. The organic material evaporated from the deposition source 200 forms the organic emission layer of an organic light emitting diode (OLED) display that includes the flexible substrate 10.

The deposition source 200 may have a crucible shape, and the organic material positioned inside the deposition source 200 may be evaporated in the direction of the supporting roll 100 (e.g., through an opening that may be formed on the deposition source 200) by heat applied inside the deposition source 200. There may be more than one opening formed on the deposition source 200.

The mask 300 is positioned between the supporting roll 100 and the deposition source 200, and includes one or more openings 310 for passing the organic material through the mask 300. The opening 310 included in the mask 300 may be, e.g., an open pattern corresponding to the organic emission layer or the wire forming the organic light emitting diode (OLED) display. The mask 300 may include a plurality of unit masks and a frame receiving and fixing the plurality of unit masks. The mask 300 may be formed of a metal material having rigidity, e.g., as stainless steel.

The organic material deposition device 1000 according to the first example embodiment may self rotate the supporting roll 100 (to which that flexible substrate 10 is attached) while the organic material is evaporated from the deposition source 200 toward the flexible substrate 10 through the opening 310 of the mask 300, thus forming the organic emission layer of the organic light emitting diode (OLED) display on the flexible substrate 10.

As described above, in the organic material deposition device 1000 according to the first example embodiment, the flexible substrate 10 may wrapped on the supporting roll 100. In an implementation, even if the flexible substrate 10 has a large size, it may not be necessary to increase the size of the supporting roll 100 supporting the large-sized flexible substrate 10. Accordingly, a compact organic material deposition device 1000 may be provided.

In the organic material deposition device 1000 according to the first example embodiment, the supporting roll 100 may be self rotated in a state where the flexible substrate 10 is rolled onto the supporting roll 100, and, during said rotation, the organic material evaporated from the deposition source 200 may be deposited on the flexible substrate 10 through the mask 300. Thus, it may be possible to avoid increases in the size of the mask 300 positioned between the supporting roll 100 and the deposition source 200. Accordingly, a center portion of the mask 300 may not sag downward, and thus the deposition reliability of the organic material for the flexible substrate 10 may be improved.

In the organic material deposition device 1000 according to the first example embodiment, the supporting roll 100 may be self rotated in a state that the flexible substrate 10 is rolled onto the supporting roll 100 and the organic material evaporated from the deposition source 200 is deposited on the flexible substrate 10 through the mask 300. Thus, even if the flexible substrate 10 has a large size, an evaporation angle of the organic material evaporated from the deposition source 200 may not decrease at the end of the mask 300. Accordingly, the organic material may be uniformly deposited on the entire surface of the flexible substrate 10, and thus the deposition reliability of the organic material for the flexible substrate 10 is improved.

Thus, although the flexible substrate 10 has a large size, the organic material deposition device 1000 may provide improved deposition reliability of the organic material for a slim and flexible substrate 10.

Next, referring to FIG. 2, an organic material deposition device according to the second example embodiment will be described.

Hereinafter, only characteristic portions that are different from the first example embodiment are described in detail; other portions for which a details are not repeated follow a description of the first example embodiment. In the second example embodiment, for better comprehension and ease of description, constituent elements identical to or corresponding to those according to the first example embodiment are denoted by the same reference numerals.

FIG. 2 is a view of an organic material deposition device according to the second example embodiment.

In the example embodiment shown in FIG. 2, the organic material deposition device 1002 according to the second example embodiment includes the supporting roll 100, a plurality of deposition sources, and a plurality of masks. The plurality of deposition sources include a first deposition source 201, a second deposition source 202, and a third deposition source 203, and the plurality of masks include a first mask 301, a second mask 302, and a third mask 303.

The first deposition source 201 is positioned at a first side (e.g., the left side) of the supporting roll 100, the second deposition source 202 is positioned at a second side (e.g., the lower side) of the supporting roll 100, and the third deposition source 203 is positioned at a third side (e.g., the right side) of the supporting roll 100. Also, the first mask 301 is positioned between the first deposition source 201 and the supporting roll 100, the second mask 302 is positioned between the second deposition source 202 and the supporting roll 100, and the third mask 303 is positioned between the third deposition source 203 and the supporting roll 100.

The organic materials respectively deposited from the first deposition source 201, the second deposition source 202, and the third deposition source 203 to the flexible substrate 10 may form the organic emission layers of the organic light emitting diode (OLED) display emitting light of different colors. For example, the organic material deposited from the first deposition source 201 to the flexible substrate 10 may form an organic emission layer emitting red light, the organic material deposited from the second deposition source 202 to the flexible substrate 10 may form an organic emission layer emitting green light, and the organic material deposited from the third deposition source 203 to the flexible substrate 10 may form an organic emission layer emitting blue light. Also, the first mask 301, the second mask 302, and the third mask 303 may respectively include openings 310 formed with opened patterns corresponding to pixels having the red organic emission layer, the green organic emission layer, and the blue organic emission layer.

The organic material deposition device 1002 according to the second example embodiment self rotates the supporting roll 100 (onto which the flexible substrate 10 is rolled) while the organic material is deposited from the first deposition source 201, the second deposition source 202, and the third deposition source 203 to the flexible substrate 10 thorough each opening 310 of the first mask 301, the second mask 302, and the third mask 303 to form the organic emission layer of the organic light emitting diode (OLED) display on the flexible substrate 10.

As described above, the organic material deposition device 1002 according to the second example embodiment simultaneously performs vertical deposition and horizontal deposition by using the first deposition source 201, the second deposition source 202, and the third deposition source 203, thereby depositing the organic material on the flexible substrate 10 at various angles. Accordingly, even though the flexible substrate 10 may have a large size, the organic material deposition device 1002 may provide improved deposition reliability of the organic material for the flexible substrate 10.

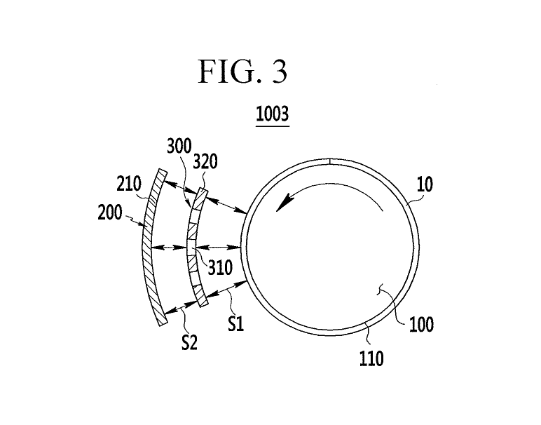

Next, referring to FIG. 3, an organic material deposition device according to the third example embodiment will be described.

Hereinafter, only characteristic portions that are different from the first example embodiment are described; portions in which a description is omitted follow a description of the first example embodiment. In the third example embodiment, for better comprehension and ease of description, constituent elements identical to or corresponding to those according to the first example embodiment are denoted by the same reference numerals.

FIG. 3 is a view of an organic material deposition device according to the third example embodiment.

In the example embodiment shown in FIG. 3, the organic material deposition device 1003 according to the third example embodiment includes a supporting roll 100, a deposition source 200, and a mask 300.

The deposition source 200 and the mask 300 are respectively bent or curved corresponding to the surface 110 of the supporting roll 100. In detail, the surface 110 of the supporting roll 100 has a predetermined curvature, and the surface 210 of the deposition source 200 and a surface 320 of the mask 300 respectively have the same predetermined curvature as the surface 110 of the supporting roll 100.

Accordingly, a center region and an outer region of the mask 300 has the same first distance Si relative to the flexible substrate 10, and the center region and the outer region of the deposition source 200 has the same second distance S2 relative to the mask 300. Thus, the same distance for the flexible substrate 10 is formed throughout the entire region of the deposition source 200.

As described above, the entire region of the mask 300 has the same first distance S1 relative to the flexible substrate 10, the entire region of the deposition source 200 has the same second distance S2 relative to the mask 300, and the entire region of the deposition source 200 has the same distance relative the flexible substrate 10. Accordingly, organic material evaporated from the deposition source 200 may be uniformly deposited across the entire surface of the flexible substrate 10 through the mask 300.

Thus, in the organic material deposition device 1003 according to the third example embodiment, by considering the flexible substrate 10 rolled onto the surface 110 of the supporting roll 100 having the predetermined curvature thereby being bent with the predetermined curvature, the mask 300 and the deposition source 200 are respectively bent with the predetermined curvature, and accordingly the organic material evaporated from the deposition source 200 is uniformly deposited throughout the entire surface of the flexible substrate 10 through the mask 300.

By way of summation and review, an organic emission layer may be formed by using an organic material deposition device. A general organic material deposition device may include a supporting member supporting a substrate as a deposition target, an evaporation (deposition) source evaporating an organic material for an organic emission layer on the substrate, and a mask positioned between the substrate and the deposition source. Recently, as the OLED display having a large area has become desired, the substrate for the large sized OLED display is formed with a large area such that the size of a supporting member supporting the large size substrate is increased, thereby causing an increase of the size of the entire organic material deposition device. Also, as a size of the mask positioned between the substrate and the deposition source is increased due to the large sized substrate, a center portion of the mask may droop downward such that the deposition reliability of the organic material for the substrate is deteriorated. Also, since the size of the mask is increased by the large sized substrate, an evaporation angle of the organic material evaporated from the deposition source is decreased at an end of the mask such that a shadow is generated for the organic material that is deposited at the end of the substrate. Such a situation may generate non-uniform deposition of the organic material at the end of the substrate, and accordingly the deposition reliability of the organic material for the substrate may be deteriorated.

As described above, embodiments relate to an organic material deposition device for forming an organic emission layer of an organic light emitting diode (OLED) display. Embodiments may provide a compact organic material deposition device even if an organic material is deposited on a large-sized substrate forming a large-sized organic light emitting diode (OLED) display. An example embodiment may provide an organic material deposition device with improved deposition reliability even if the organic material is deposited on the large-sized substrate forming a large-sized organic light emitting diode (OLED) display. Also, even though the organic material is deposited on the large-sized substrate forming the large-sized OLED display, improved deposition reliability may be provided.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A deposition device for depositing an organic material, the device comprising:
a supporting roll having a surface, the surface being configured to receive a flexible substrate thereon, the supporting roll being configured to rotate;
a deposition source spaced apart from the supporting roll, the deposition source being configured to deposit the organic material on the flexible substrate on the supporting roll; and
a mask positioned between the supporting roll and the deposition source, the mask including an opening configured to allow the organic material to pass from the deposition source to the supporting roll.

2. The device as claimed in claim 1, wherein the organic material forms an organic emission layer of an organic light emitting diode display on the flexible substrate.

3. The device as claimed in claim 1, wherein:
a plurality of deposition sources is provided, the plurality of deposition sources including:
a first deposition source, the first deposition source being positioned to face the surface of the supporting roll at a first side of the supporting roll;
a second deposition source, the second deposition source being positioned to face the surface of the supporting roll at a second side of the supporting roll; and
a third deposition source, the third deposition source being positioned to face the surface of the supporting roll at a third side of the supporting roll, and
a plurality of masks is provided, the plurality of masks including:
a first mask positioned between the first deposition source and the surface of the supporting roll;
a second mask positioned between the second deposition source and the surface of the supporting roll; and
a third mask positioned between the third deposition source and the surface of the supporting roll.

4. The device as claimed in claim 3, wherein the first deposition source, the second deposition source, and the third deposition source are configured to deposit respective organic materials to form an organic emission layer of an organic light emitting diode display emitting light having different colors.

5. The device as claimed in claim 1, wherein the deposition source and the mask are each curved.

6. The device as claimed in claim 5, wherein:
the surface of the supporting roll has a predetermined curvature, and
a surface of the deposition source and the mask each have the predetermined curvature.

7. The device as claimed in claim 1, wherein the deposition source and the mask are each substantially planar.

8. The device as claimed in claim 1, wherein the supporting roll is configured to rotate about an axis and thereby translate the flexible substrate in front of the deposition source.
